(19) United States
(12) Patent Application Publication
(10) Pub. No.: US 2004/0086014 A1
(43) Pub. Date: May 6, 2004

(54) Semiconductor laser having emitting wavelength

(75) Inventor: Ching-Fuh Lin, Taipei (TW)

Correspondence Address: Webb Ziesenheim Logsdon, Orkin & Hanson, P.C, 700 Koppers Building, 436 Seventh Avenue, Pittsburgh, PA, 15219-1818, US

(73) Assignee: ARIMA OPTOELECTRONICS CORP.

(21) Appl. No.: 10/417,860

(22) Filed: Apr. 17, 2003

(30) Foreign Application Priority Data
Nov. 4, 2002 (TW) 091132532

(51) Int. Cl. H01S 5/00

(52) U.S. Cl. 372/45

(57) ABSTRACT

A semiconductor laser having an emitting wavelength is disclosed. The semiconductor laser having an emitting wavelength includes plural quantum well groups respectively having quantized energy levels wherein the quantized energy levels are mutually different. The emitting wavelength of the semiconductor laser is set in one of the plural quantum well groups having a relatively high quantized energy level for reducing a temperature effect on the semiconductor laser.

### FIELD OF THE INVENTION

This invention relates to a semiconductor laser, and more particularly to a semiconductor laser having an emitting wavelength.

### BACKGROUND OF THE INVENTION

The broadest application among many kinds of laser illuminants is the laser produced by semiconductor. Semiconductor laser illuminants have the characteristics of small size, low power dissipation and low cost, and so on, generally used in optical fiber communication. However, it is very important to reduce the temperature effects on the semiconductor lasers for the application of semiconductor lasers. For example, many factors like nonradiative recombination, leakage currents, carrier recombination in separate confinement heterostructure (SCH) layers, and so on, usually have increasing influences with temperature. These factors degrade laser characteristics at high temperature.

Since the researches of multiple quantum wells (MQW) started in 1974, the developing tendency of the designs for semiconductor lasers using superlattice structure became to set up a separate flag. The semiconductor lasers have the advantages of high efficiency, low threshold current and high modulation frequency. It is the best choice of laser illuminants for advanced optics system. In the Taiwan Patent No. 469656, it has mentioned a semiconductor light emitting diode structure with a multiple quantum wells and the approach of sending out multiple wavelengths via the structure. Please refer to FIG. 1, which is a schematic diagram of general semiconductor laser structure including a substrate 11, a N-type shell 12, an active layer 13 and a P-type shell 14. The quantum wells located in the active layer 13.

The semiconductor lasers usually have the operating currents increasing with temperature. Also, under a fixed injection current, the output power decreases with temperature. Particularly, the conventional InGaAsP or InP quantum well long-wavelength laser diodes for optical fiber communication are very temperature-sensitive. Therefore, their applications are limited in a narrow temperature range or quite complicated cooling techniques are required to maintain the operation temperature of the semiconductor lasers.

Seldom mechanisms are found to improve temperature characteristics for semiconductor lasers except alternating material system to AlGaInAs or InP, but introducing aluminum into laser layer structure increases difficulties in epitaxy and reliability. Recent efforts using InGaAsN or GaAs still cannot achieve satisfactory characteristics. Some have used the stacking mirror of vertical-cavity surface emission lasers designed for a wavelength slightly longer than the corresponding wavelength of quantum wells in active region. As temperature increases, the red-shift of the gain in quantum wells makes the gain peak better match the wavelength of the stacking mirror. The gain at low temperature is sacrificed. In addition, the stacking mirror also varies with temperature, so the design to match the gain peak and the stacking mirror period is very critical, leading to the complexity of fabrication. Similar techniques can be applied to the distributed-feedback laser. The distributed grating mirror also has a wavelength designed slightly longer than the corresponding wavelength of quantum wells in active region. As temperature increases, the red-shift of the gain in quantum wells makes the gain peak better match the wavelength of the grating period. Similarly, the gain at low temperature is sacrificed and the grating period also varies with temperature, so the design to match the gain peak and the grating period is very critical, leading to the complexity of fabrication.

Because of the technical defects according to prior arts, the applicant keeps on carving unflaggingly to develop “semiconductor laser having emitting wavelength” through wholehearted experience and research.

### SUMMARY OF THE INVENTION

It is an object of the present invention to utilize a nature property of carrier distribution that varies with temperature. The quantum wells of the semiconductor laser include plural quantum well groups respectively having quantized energy levels wherein the quantized energy levels are mutually different. The emitting wavelength of the semiconductor laser is set in one of the plural quantum well groups having a relatively high quantized energy level for reducing a temperature effect on the semiconductor.

It is another object of the present invention to provide a semiconductor laser having an emitting wavelength. The present invention utilizes a nature property of carrier distribution that varies with temperature. This makes the reduction of temperature influence and simplifies the implementation of the proposed techniques in the semiconductor lasers.

It is another object of the present invention to provide a semiconductor laser having an emitting wavelength. The semiconductor laser having an emitting wavelength includes plural quantum well groups respectively having quantized energy levels wherein the quantized energy levels are mutually different. Each quantum well group includes at least a quantum well. The emitting wavelength of the semiconductor laser is set in one of the plural quantum well groups having a relatively high quantized energy level for reducing a temperature effect on the semiconductor.

In accordance with an aspect of the present invention is to provide a semiconductor laser having an emitting wavelength. The semiconductor laser having an emitting wavelength includes plural quantum well groups respectively having quantized energy levels wherein the quantized energy levels are mutually different. Each quantum well group includes at least a quantum well. The emitting wavelength of the semiconductor laser is set in one of the plural quantum well groups having a relatively high quantized energy level for reducing a temperature effect on the semiconductor.

Preferably, the semiconductor laser has an active layer.

Preferably, the quantum wells groups are located in the active layer.

Preferably, the energy differences among the plural quantum well groups have a value ranged from 3 meV to 500 meV.

Preferably, each quantum well group further includes at least a quantum well.

Preferably, the quantum well is made of InGaAs.

Preferably, the quantum well is made of InGaAsP.

Preferably, the emitting wavelength is ultraviolet.

Preferably, the emitting wavelength is visible light.

Preferably, the emitting wavelength is infrared.

Preferably, the relatively high-quantized energy level is free of the lowest quantized energy level.

Preferably, the semiconductor laser further includes plural barrier layers respectively disposed between every two quantum well groups.

In accordance with another aspect of the present invention is to provide a semiconductor laser having an emitting wavelength. The semiconductor laser having an emitting wavelength includes plural quantum well groups respectively having quantized energy levels wherein the quantized energy levels are mutually different and the emitting wavelength of the semiconductor laser is set in one of the plural quantum wells groups having a relatively high quantized energy level, and plural barrier layers respectively disposed between every two quantum well groups.

Preferably, the semiconductor laser has an active layer.

Preferably, the quantum wells groups are located in the active layer.

Preferably, the energy differences among the plural quantum well groups have a value ranged from 3 meV to 500 meV.

Preferably, each quantum well group further includes at least a quantum well.

Preferably, the quantum well is made of InGaAs.

Preferably, the quantum well is made of InGaAsP.

Preferably, the relatively high-quantized energy level is free of the lowest quantized energy level.

### BRIEF DESCRIPTION OF THE DRAWINGS

FIG. 1 shows a schematic diagram of the general semiconductor laser according to prior arts;

FIG. 2 shows a schematic diagram of nonidentical multiple quantum wells (MQW) energy band with two different quantum wells (QWs) according to a preferred embodiment of the present invention;

FIG. 3(a) shows a density of states diagram at low temperature and high temperature for the first quantum well according to a preferred embodiment of the present invention;

FIG. 3(b) shows a density of states diagram at low temperature and high temperature for the second quantum well according to a preferred embodiment of the present invention;

FIG. 4 shows a variation of transition energy with temperature according to a preferred embodiment of the present invention; and

FIG. 5 shows variation of threshold current of long-wavelength and short-wavelength modes with temperature according to a preferred embodiment of the present invention.

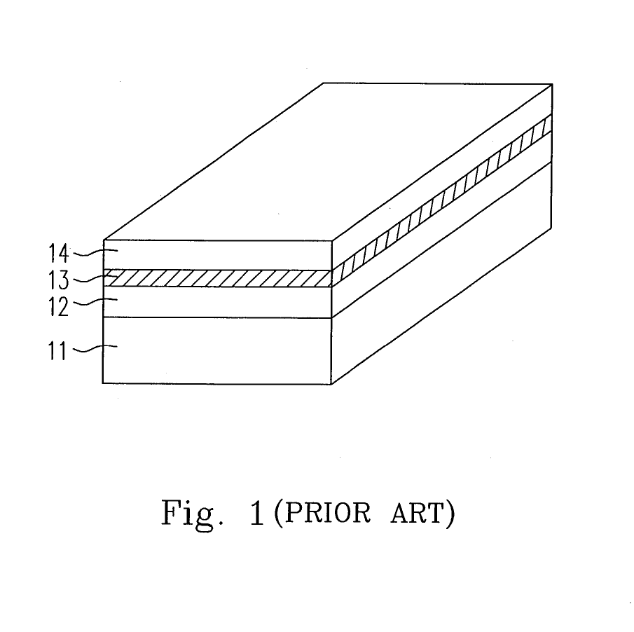

### DETAILED DESCRIPTION OF THE PREFERRED EMBODIMENT

The present invention will now be described more specifically with reference to the following embodiments.

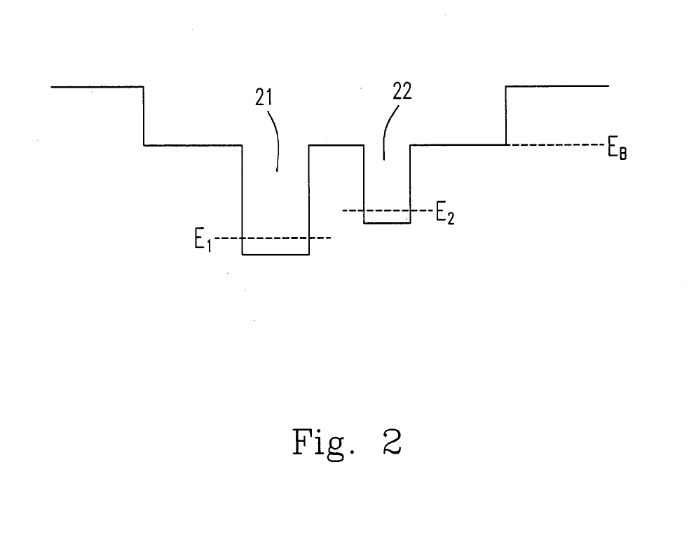

For improving the disadvantages of prior arts, the present invention utilizes a nature property of carrier distribution that varies with temperature. This makes the reduction of temperature influence and simplifies the implementation of the proposed techniques in the semiconductor lasers. The carrier distribution is governed by the Fermi-Dirac distribution, which favors more carriers in the high energy states at high temperature. Please refer to FIG. 2. It schematically shows a semiconductor laser that consists of two different quantized energy level of quantum wells structure. It includes a first quantum well 21 and a second quantum well 22. The first quantum well 21 and the second quantum well 22 have different quantized energy level at E1 and E2, respectively. Assume that E1 is much less than E2. As the semiconductor laser structure is under forward bias, carriers are injected into first quantum well 21 and second quantum well 22. The quasi Fermi level is higher than the quantized levels E1 and E2. For the simplicity of discussion without loss of generality, the quasi Fermi level is assumed to be the same for both E1 and E2. The Fermi level usually varies with temperature. However, the variation is small as long as the number of injected carriers is not changed, so the variation is neglected.

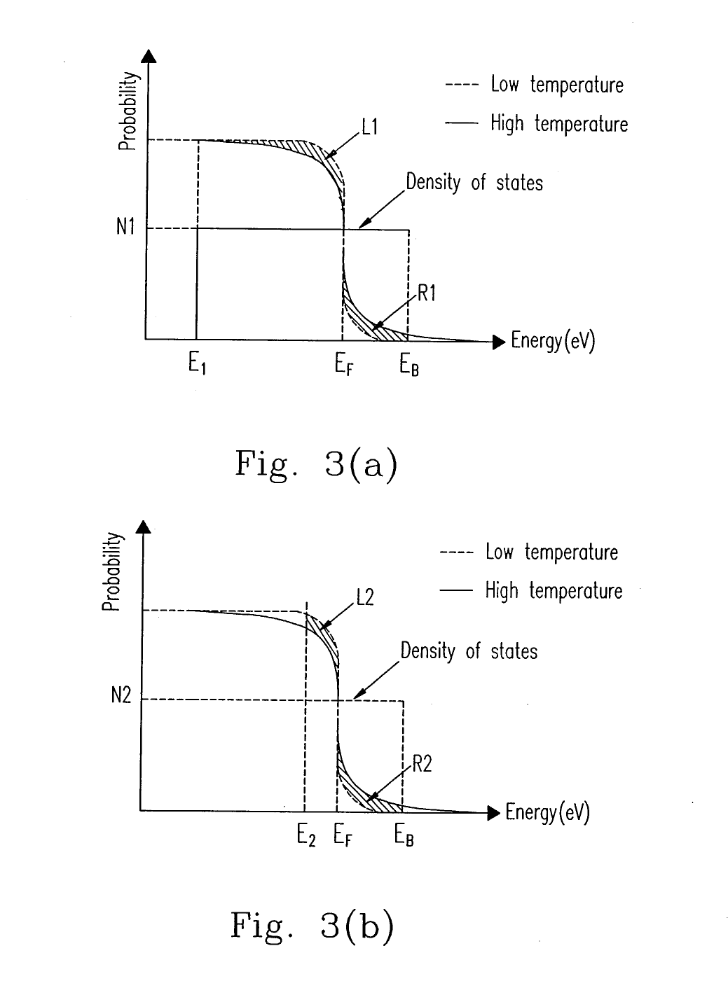

Please refer to FIG. 3(a) and FIG. 3(b), both two are the densities of states for the first quantum well 21 and the second quantum well 22, respectively. As temperature increases, the Fermi-Dirac distribution changes and causes carriers to move into the high-energy states. As a result, carriers in first quantum well 21 and second quantum well 22 change the number of N1(R1-L1) and N2(R2-L2), respectively. N1 and N2 are the density of states for the first quantum well 21 and the second quantum well 22. In some circumstances, it is possible that Fermi level (E_{f}) is closer to barrier energy (E_{B}) than E1 for the first quantum well 21 and closer to E2 for the second quantum well 22. Because the shaded area R1 is less than L1, the number of carriers in the first quantum well 21 decreases. On the contrary, the shaded area R2 is larger than L2, the number of carriers in the second quantum well 22 increases. When the injection current is fixed, the total amount of carriers in quantum wells is approximately constant. Therefore, carriers flow from the first quantum well 21 to the second quantum well 22 as temperature increases and vice versa as temperature decreases.

Because the carriers in the second quantum increase with temperature, the corresponding gain will increase too. If the lasing wavelength is controlled to the second quantum well (e.g. using distributed grating or external feedback), the lasing mode will have increasing gain with temperature. On the other hands, nonradiative recombination, leakage currents, carrier recombination in separate confinement heterostructure layers, and so on, increase with temperature and reduce the gain of quantum wells. Those two opposite effects could compensate one another to reduce the overall variation with temperature.

Now, an example is used to explain the method of the present invention. At first, fabricate a semiconductor laser that consists of two different quantized energy levels of quantum wells. The first type consists of two In_{0.53}Ga_{0.47}As and the second type consists of three In_{60.7}Ga_{0.33}As_{0.72}P_{0.28}. The two In_{0.53}Ga_{0.47}As quantum wells are near the p-cladding layer and three In_{0.67}Ga_{0.33}As_{0.72}P_{0.28} quantum wells are near the n-cladding layer. The first type quantum well and the second type quantum well are separated by In_{0.86}Ga_{0.14}As_{0.3}P_{0.7} barriers.

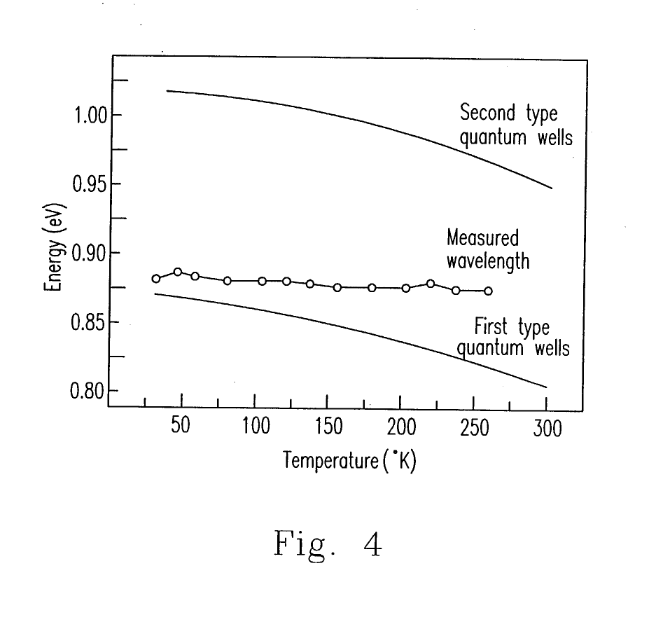

At room temperature, the first type quantum well and the second type quantum well have the first quantized transition energy of 0.8 eV and 0.954 eV, respectively. Because the bandgap shrinks with temperature, the transition energy decreases with temperature, as shown in FIG. 4. The measured wavelength of the above semiconductor lasers shows much less temperature dependence. When temperature rises from 33 K to 260 K, the corresponding energy changes less then 5 meV while the bandgap energy changes more than 50 meV. As explained previously, because carriers decreases in the first quantum well and increase in the second quantum well when temperature increases, the lasing wavelength shifts toward the energy corresponding to the second quantum well, and reduce the influences of temperature variation.

When temperature increases near to room temperature, the threshold current and operation current increase and cause more carriers to be captured into the second type quantum wells. Because the temperature and the carrier injection increase, it causes the carrier to reside in the second quantum wells, such quantum wells structures contribute more gain to lasing modes. Therefore, another cluster of Fabry-Perot modes at short wavelength appears. The peak wavelengths of the two clusters of modes are around 1365 nm and 1415 nm, respectively.

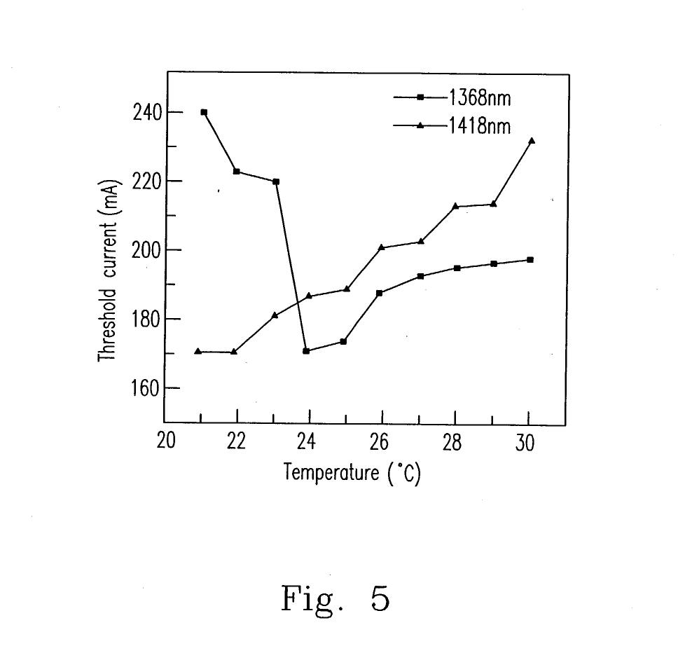

Because the two clusters of lasing wavelengths are separated spectrally, it is easy to measure the lasing powers separately. As temperature increases, the lasing power of the short-wavelength modes increases, and the lasing power of the long-wavelength modes decreases. This further indicates that the carriers move from the first quantum wells to the second quantum wells. Please refer to FIG. 5, schematically showing the preferred embodiment of the present invention contrasted to the threshold current. The threshold current of the short-wavelength modes is less than that of the long-wavelength modes for temperature beyond 24 C. The threshold current of the short-wavelength modes decreases in the temperature range between 21 C and 24 C. It implies that those modes have negative characteristic temperature. Using such effects of negative characteristic temperature, it is possible to override the bad effects (e.g. leakage current or Auger recombination) caused by temperature increase via carrier distribution among nonidentical quantum wells. The first quantum wells have the function like reservoirs to overcome the detrimental influence of temperature.

The above examples show that if the lasing wavelength is controlled to wavelengths corresponding to the high-energy quantum wells (short-wavelength), the threshold current will not increase with temperature like the usual laser diodes. On the contrary, the threshold may decrease with temperature. The control of the lasing wavelength may be achieved by using distributed Bragg grating, distributed feedback grating or external feedback from an external grating in the external-cavity configuration.

The carriers equivalently move from low-energy quantum wells to high-energy quantum wells when temperature increases. The lasing wavelength moves from the one corresponding to low-energy quantum wells to the high-energy quantum wells, which will lead to blue-shift of lasing modes. However, the quantum wells energy usually decreases with temperature, which results in red-Shift of lasing modes. Therefore, the two opposite effects could compensate for one another to give a small temperature variation of lasing wavelengths, as shown in FIG. 4.

The above examples are one of the preferred embodiments of the present invention and only for demonstration of the idea. For applications, the quantum wells are not limited to the shown material ingredients. Also, the types and numbers of quantum wells are not limited to the above demonstration. The quantum wells may be two types or more than two types in the present invention. It could use three, four or five types, for example. It only needs to control the energy differences among every quantum well for a certain value (ranged from 3 meV to 500 meV). The number of quantum wells depends on circumstances. It could consist of one, two, three or more quantum wells and could not affect the effect of the present invention. The lasing wavelength is controlled to the high-energy quantum wells for achieving the characteristic effects. The working wavelengths could be UV, visible, IR, and so on.

In conclusion, the present invention utilizes a nature property of carrier distribution that varies with temperature. The quantum wells of the semiconductor laser include plural quantum well groups respectively having quantized energy levels wherein the quantized energy levels are mutually different. The emitting wavelength of the semiconductor laser is set in one of the plural quantum well groups having a relatively high-quantized energy level. This makes the reduction of temperature influence and simplifies the implementation of the proposed techniques in the semiconductor lasers. Because of the reasons described above, the present invention provides the substantially preferred aids for industrial development.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. The semiconductor laser having an emitting wavelength, comprising:
plural quantum well groups respectively having quantized energy levels wherein said quantized energy levels are mutually different, and said emitting wavelength of said semiconductor laser is set in one of said plural quantum well groups having a relatively high quantized energy level for reducing a temperature effect on said semiconductor.

2. The semiconductor laser as claimed in claim 1, wherein said semiconductor laser has an active layer.

3. The semiconductor laser as claimed in claim 2, wherein said quantum wells groups are located in said active layer.

4. The semiconductor laser as claimed in claim 1, wherein said energy differences among said plural quantum well groups have a value ranged from 3 meV to 500 meV

5. The semiconductor laser as claimed in claim 1, wherein each said quantum well group further comprises at least a quantum well.

6. The semiconductor laser as claimed in claim 5, wherein said quantum well is made of InGaAs.

7. The semiconductor laser as claimed in claim 5, wherein said quantum well is made of InGaAsP.

8. The semiconductor laser as claimed in claim 1, wherein said emitting wavelength is ultraviolet.

9. The semiconductor laser as claimed in claim 1, wherein said emitting wavelength is visible light.

10. The semiconductor laser as claimed in claim 1, wherein said emitting wavelength is infrared.

11. The semiconductor laser as claimed in claim 1, wherein said relatively high-quantized energy level is free of the lowest quantized energy level.

12. The semiconductor laser as claimed in claim 1 further comprising:
plural barrier layers respectively disposed between every said two quantum well groups.

13. The semiconductor laser having an emitting wavelength, comprising:
plural quantum well groups respectively having quantized energy levels wherein said quantized energy levels are mutually different, and said emitting wavelength of said semiconductor laser is set in one of said plural quantum wells groups having a relatively high quantized energy level; and
plural barrier layers respectively disposed between every said two quantum well groups.

14. The semiconductor laser as claimed in claim 13, wherein said semiconductor laser has an active layer.

15. The semiconductor laser as claimed in claim 14, wherein said quantum wells groups are located in said active layer.

16. The semiconductor laser as claimed in claim 13, wherein said energy differences among said plural quantum well groups have a value ranged from 3 meV to 500 meV.

17. The semiconductor laser as claimed in claim 13, wherein each said quantum well group further comprises at least a quantum well.

18. The semiconductor laser as claimed in claim 13, wherein said quantum well is made of InGaAs.

19. The semiconductor laser as claimed in claim 13, wherein said quantum well is made of InGaAsP.

20. The semiconductor laser as claimed in claim 13, wherein said relatively high-quantized energy level is free of the lowest quantized energy level.
